(19) United States
(12) Patent Application Publication
(10) Pub. No.: US 2017/0044667 A1
(43) Pub. Date: Feb. 16, 2017

(54) PHOTO-ASSISTED ATOMIC LAYER DEPOSITION METHOD

(71) Applicant: G-FORCE NANOTECHNOLOGY LTD., Kaohsiung City (TW)

(72) Inventors: Chao-Hui Yeh, KAOHSIUNG CITY (TW); Jen-Kuan Chiu, KAOHSIUNG CITY (TW)

(73) Assignee: G-FORCE NANOTECHNOLOGY LTD., Kaohsiung City (TW)

(21) Appl. No.: 15/093,863

(22) Filed: Apr. 8, 2016

(30) Foreign Application Priority Data
Aug. 10, 2015 (TW) 104125979

(51) Int. Cl. C23C 16/455

(52) U.S. Cl. CPC C23C 16/45512

(57) ABSTRACT

A photo-assisted atomic layer deposition method includes the following steps: preparing a processing system having a processing chamber and a first gas input channel connecting the processing chamber, and the first gas input channel having a pre-chamber with a transparent side wall; introducing a first gas into the pre-chamber; illuminating the interior space of the pre-chamber by ultraviolet light via the transparent side wall; and injecting the first gas illuminated by the ultraviolet light into the processing chamber. The reactivity of the first gas can be promoted by the illumination of the ultraviolet light in the pre-chamber, so that the first gas illuminated by the ultraviolet light becomes more active to react completely in the process of film depositions, with reduced ligand residues in the deposited films.

### BACKGROUND OF THE INVENTION

1. Field of the Invention

The present invention relates to a photo-assisted atomic layer deposition method, and more particularly, the present invention relates to a photo-assisted atomic layer deposition method capable of increasing reaction rate in the process of film depositions, reducing ligands in the deposited films and optimizing the atomic layer deposition.

2. Description of the Prior Art

Atomic layer deposition is a method to form a single atomic layer from the adsorbed molecule on the surface of the substrate. The atomic layer deposition is similar to the chemical vapor deposition (CVD), but every new atomic layer is relevant to the last atomic layer in the atomic layer deposition. Therefore, there is only one layer of molecules after every reaction. The atomic layer deposition is able to obtain a uniform thickness of layer deposited and an exact control of thickness by self-controlling and uniformly covering. Generally, two different kinds of gas reactants are introduced into the processing chamber in turn to deposit on the substrate in the atomic layer deposition. These gas reactants are called precursors.

Take Al₂O₃ deposition on a silicon substrate as an example. Firstly, the surface of the silicon which is predetermined to be deposited by Al₂O₃ is processed to absorb hydroxyls. Then, the precursor, Al(CH₃)₃, is introduced into the processing chamber. As Al(CH₃)₃ reacts with hydroxyls, a chemical bond is formed between aluminum and oxygen. CH₄ is generated in the reaction and leaves the surface under the vacuum conditions. When the hydroxyl groups are completely reacted, Al(CH₃)₃ can no longer adsorb on the silicon surface, limiting the surface reaction to a single molecule scale. Then, residual Al(CH₃)₃ is removed, and water is introduced into the processing chamber. Water molecules react with methyl groups (CH₃) to form the new hydroxyl groups atop of the alumina. The other two methyl groups react with water molecules to form oxygen bonds between two adjacent aluminum atoms through a dehydration reaction. A single atomic layer is formed after the processes mentioned above. The processes are repeated to form a plurality of atomic layers.

The atomic layer deposition is able to obtain a uniform thickness of layers deposited, an exact control of thickness, and a high aspect ratio. However, the deposition process is often limited by the choice of precursors which are required to possess high reactivity at a reaction temperature between 100 to 300° C. In addition, ligand residuals in the deposited films play a central role in the quality of deposited film. In the prior arts, plasma has been used to assist the complete decomposition of precursor involved in the reaction and to increase the deposition rate.

In the prior art, photo-assisted reaction is applied in a CVD system, wherein a transparent conduit is connected between a plasma generator and a CVD chamber, and an ultraviolet (UV) light illuminating the transparent conduit is provided to maintain the activation of the active species from the plasma generator. The disadvantages of the process in the prior art are as follows: (1) The temperature of the precursor illuminated by the UV light cannot be controlled independently, neither to the illumination time. (2) The long conduit is generally made of quartz or glass. A large portion of UV light is significantly adsorbed when the UV light passes through the long conduit, leading to a remarkable reduction of UV intensity and an ineffective illumination accordingly. (3) To provide the UV light with enough intensity, the power of the UV light should be enlarged, increasing the cost of facility. (4) Since the conduit is not spatially separated from the reaction chamber, there might be a plurality of films deposited on the inner wall of the long conduit, leading to the reduction of the transparence of the conduit quartz or glass.

As mentioned above, it is essential to provide a new photo-assisted atomic layer deposition method that are able to improve the reactivity of the precursor efficiently, to improve the growth rate, and to reduce the residuals of the ligand functional groups in the deposited films.

### SUMMARY OF THE INVENTION

One scope of the present invention is providing a photo-assisted atomic layer deposition which comprises the following steps: preparing a processing system including a processing chamber and a plurality of gas input channels, wherein the processing chamber is used for containing a substrate and connected to a first gas input channel of the plurality of gas input channels, the first gas input channel includes a pre-chamber and a heating device, the pre-chamber includes a transparent side wall and is separated from the processing chamber by a first valve; starting the heating device to raise the temperature of the pre-chamber to a predetermined temperature; closing the first valve and introducing a first gas into the pre-chamber of the first gas input channel; illuminating the interior space of the pre-chamber by an ultraviolet light via the transparent side wall for a predetermined duration; and, opening the first valve to input the first gas illuminated by the ultraviolet light into the processing chamber to form atomic layers on the substrate.

Because the first gas is illuminated by the ultraviolet light in the pre-chamber of the first gas input channel, the reactivity of the first gas in the processing chamber is raised to form an atomic layer on the substrate efficiently. Besides, in the design of the pre-chamber, the planar transparent side wall is able to be made of the material with low absorption coefficient like MgF₂, outperforming the prior art with the smaller illumination area and the less illumination intensity of the ultraviolet light.

The pre-chamber of the first gas input channel and the processing chamber are separable via a vacuum valve, so that the duration of illuminating the ultraviolet light is controllable separately. The temperature of the precursor illuminated by the ultraviolet light can also be controlled separately, so as to reduce the ligand residues of the precursor.

The pre-chamber of the first gas input channel and the processing chamber is separable via a vacuum valve to block any deposition occurred on the transparent side wall of the pre-chamber, so as not to degrade the illumination intensity of the ultraviolet light in the atomic layer deposition and the CVD process.

Another scope of the present invention is providing a photo-assisted atomic layer deposition method; according to another embodiment, the photo-assisted atomic layer deposition method further comprises the following step of: heating the pre-chamber to keep the temperature of the pre-chamber in a temperature range from 25° C. to 400° C.

Another scope of the present invention is providing a photo-assisted atomic layer deposition method; according to another embodiment, the thickness of the atomic layer in every single deposition process is less than 1 nm.

Another scope of the present invention is providing a photo-assisted atomic layer deposition method; according to another embodiment, in the deposition process of atomic layer in the embodiment mentioned above, the predetermined duration of ultraviolet light illumination is in a range from 0.1s to 10s.

Another scope of the present invention is providing photo-assisted atomic layer deposition method; according to another embodiment, the wavelength of the ultraviolet light in the embodiment mentioned above is in a range from 160 nm to 360 nm, and the power is in a range from 100 Watts to 500 Watts. The temperature of the substrate heated by the processing chamber is in a range from 25° C. to 800° C. The flow rate of the react gas is in a range from 20 sccm to 5000 sccm.

Another scope of the present invention is providing a photo-assisted atomic layer deposition method; according to another embodiment, the reacting gas in the embodiment mentioned above comprises at least one of Ti, Zr, Hf, Nb, Ta, Cr, Mo, W, Re, Fe, Co, Ni, Si, Ge, In, Sn and Ga compounds. The second gas comprises at least one of oxygen, water, hydrogen and nitrogen.

Another scope of the present invention is providing a photo-assisted atomic layer deposition method; according to another embodiment, the transparent side wall of the pre-chamber in the embodiment mentioned above is made of one of magnesium fluoride, quartz and glass with high penetrability of the ultraviolet light.

Another scope of the present invention is providing a photo-assisted atomic layer deposition method; according to another embodiment, the photo-assisted atomic layer deposition method further comprises the following steps of: closing the first valve between the first gas input channel and the processing chamber to keep the first gas in the pre-chamber when the first gas is introduced into the pre-chamber.

Another scope of the present invention is providing a photo-assisted atomic layer deposition method; according to another embodiment, the photo-assisted atomic layer deposition method further comprises the following steps of: opening the first valve to input the first gas illuminated by the ultraviolet light into the processing chamber when the first gas has been illuminated by the ultraviolet light for a predetermined duration in the pre-chamber.

Another scope of the present invention is providing a photo-assisted atomic layer deposition method; according to another embodiment, the photo-assisted atomic layer deposition method further comprises the following steps of: introducing the second gas into the pre-chamber of the first gas input channel via a second gas input channel.

Another scope of the present invention is providing a photo-assisted atomic layer deposition method; according to another embodiment, the photo-assisted atomic layer deposition method further comprises the following steps of: introducing the second gas and the first gas from the pre-chamber into the processing chamber to form the atomic layer on the substrate.

Another scope of the present invention is providing a photo-assisted atomic layer deposition method; according to another embodiment, the photo-assisted atomic layer deposition method further comprises the following steps of: introducing the second gas into the processing chamber via the second gas input channel to form the atomic layer on the substrate.

Another scope of the present invention is providing a photo-assisted atomic layer deposition method; according to another embodiment, the photo-assisted atomic layer deposition method further comprises following steps of: introducing the third gas into the processing chamber via a third gas input channel.

Another scope of the present invention is providing a photo-assisted atomic layer deposition method; according to another embodiment, the third gas introduced into the processing chamber via the third gas input channel is plasma gas or an inert gas, wherein the inert gas comprises nitrogen and argon.

Another scope of the present invention is providing a photo-assisted atomic layer deposition method; according to another embodiment, the photo-assisted atomic layer deposition method further comprises the following steps of: alternatively opening and closing the first valve and a second valve which connects the second gas input channel to the processing chamber in turns, so as to introduce the first gas and the second gas into the processing chamber in turns to form the atomic layers on the substrate.

The advantages and spirits of the invention may be understood by the following recitations together with the appended drawings.

### BRIEF DESCRIPTION OF THE APPENDED DRAWINGS

Some of the embodiments will be described in detail, with reference to the following figures, wherein like designations denote like members, wherein:

FIG. 1A shows the flow chart of the photo-assisted atomic layer deposition method according to an embodiment of the present invention.

FIG. 1B shows the diagram of a processing system applying the photo-assisted atomic layer deposition method of FIG. 1A.

FIG. 2 shows the flow chart of a photo-assisted atomic layer deposition method according to another embodiment of the present invention.

FIG. 3 shows the flow chart of a photo-assisted atomic layer deposition method according to another embodiment of the present invention.

FIG. 4A shows the flow chart of a photo-assisted atomic layer deposition method according to another embodiment of the present invention.

FIG. 4B shows the diagram of the processing system applying the photo-assisted atomic layer deposition method of FIG. 4A.

FIG. 4C shows the flow chart of a photo-assisted atomic layer deposition method according to another embodiment of the present invention.

FIG. 5A shows the flow chart of a photo-assisted atomic layer deposition method according to another embodiment of the present invention.

FIG. 5B shows the diagram of the processing system applying the photo-assisted atomic layer deposition method of FIG. 5A.

FIG. 5C shows the flow chart of a photo-assisted atomic layer deposition method according to another embodiment of the present invention.

### DETAILED DESCRIPTION OF THE INVENTION

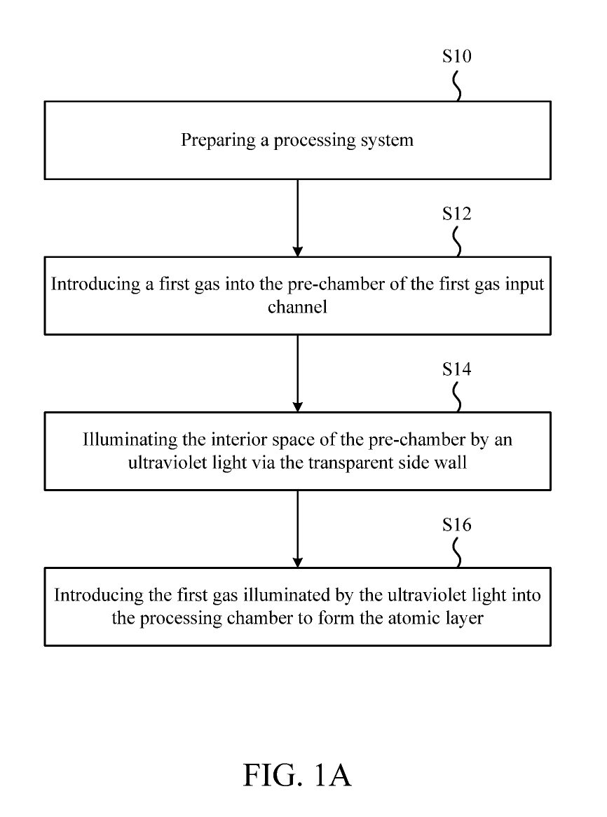

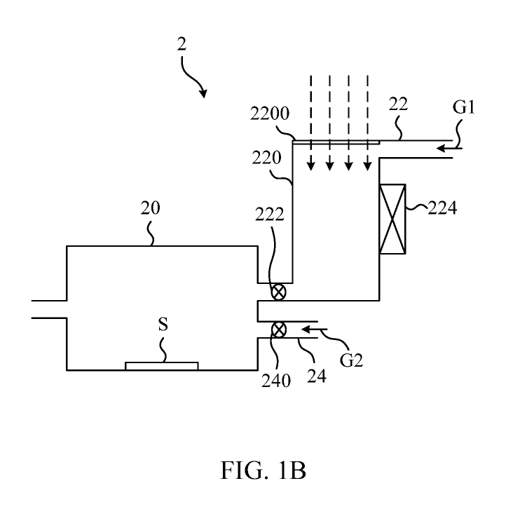

Please refer to FIG. 1A and FIG. 1B. FIG. 1A shows flow chart of the photo-assisted atomic layer deposition method according to an embodiment of the present invention. FIG. 1B shows the diagram of a processing system applying the photo-assisted atomic layer deposition method of FIG. 1A. A processing system 2 used in a photo-assisted atomic layer deposition method in the embodiments comprises a processing chamber 20 and a first gas input channel 22 connected to the processing chamber 20, wherein the processing chamber 20 is used for placing the substrate S therein, and a processing gas used in the photo-assisted atomic layer deposition method is introduced into the processing chamber 20 to form an atomic layer on the substrate S. Besides, the first gas input channel 22 further comprises a pre-chamber 220 and a first valve 222. One of the side walls of the pre-chamber 220 is a transparent side wall 2200. The light illuminates the interior space of the pre-chamber 220 via the transparent side wall 2200. The transparent side wall is made of one among magnesium fluoride, quartz and glass with high penetrability of the ultraviolet light. The first valve 222 connects the first gas input channel 22 and the processing chamber 20. The gas from the first input channel 22 is able to flow into the processing chamber 20 or is blocked by closing the first valve 222. The left outlet of the processing chamber 20 is able to be connected to an exhausting apparatus which is not shown in the figure to input or output the process gas or the other gas in or out of the processing chamber 20, and to maintain the pressure in the processing chamber 20. Besides, the pre-chamber 220 is connected to the heating device 224, and the temperature of the pre-chamber 220 heated by the heating device 224 is in a range from 25° C. to 400° C.

As shown in FIG. 1A and FIG. 1B, the photo-assisted atomic layer deposition method comprises the following steps of: in the step S10, preparing a processing system 2 in FIG. 1B; in the step S12, introducing a first gas G1 into the pre-chamber 220 of the first gas input channel 22; in the step S14, illuminating the interior space of the pre-chamber 220 via the transparent side wall 2200 by the ultraviolet light; and in the step S16, introducing the first gas G1 illuminated by the ultraviolet light into the processing chamber 20 to form the atomic layer on the substrate S.

In the step S10, the structures of the processing chamber 20 and the first gas input channel 22 of the processing system 2 were mentioned on the above paragraph. In practice, the processing chamber 20 and the first gas input channel 22 are able to be connected to different objects to achieve the process of the photo-assisted atomic layer deposition method. For example, the processing chamber 20 is able to be connected to an exhausting apparatus and another heating device to make suitable process conditions in the processing chamber. In another example, the first gas input channel 22 is able to be connected to a storage tank of the first gas G1. In practice, the processing chamber 20 is connected to another heating device to heat the substrate S in the processing chamber 20 to make the temperature in a range from 25° C. to 800° C. for the atomic layer deposition.

In step S12, the first gas G1 is introduced into the pre-chamber 220 of the first gas input channel 22. As mentioned above, the first gas input channel 22 is able to be connected to the storage tank of the first gas G1, so the first gas G1 is able to be introduced into the pre-chamber 220 from the storage tank. In step S14, the ultraviolet light is provided from an ultraviolet light generator. Please refer to FIG. 1A. Because the pre-chamber 220 is extended perpendicularly to the first gas input channel 22, and the transparent side wall 2200 faces to the extending direction of the pre-chamber 220, so the ultraviolet light can readily illuminate all space of the pre-chamber. The first gas G1 can be illuminated efficiently without enlarging the exposure area of the ultraviolet light. In step 16, the first gas G1 has higher chemical reactivity after being illuminated by the ultraviolet light to form an atomic layer on the substrate.

In the embodiment, because of the design of the pre-chamber 220 and the transparent side wall 2200, the first gas G1 can be effectively illuminated by sufficient ultraviolet light in the pre-chamber 220 to reduce the reaction time for each cycle. To make sure enough illumination on the first gas G1 by the ultraviolet light, the first gas G1 is able to stay in the pre-chamber 220 for a longer duration before getting into the processing chamber 20.

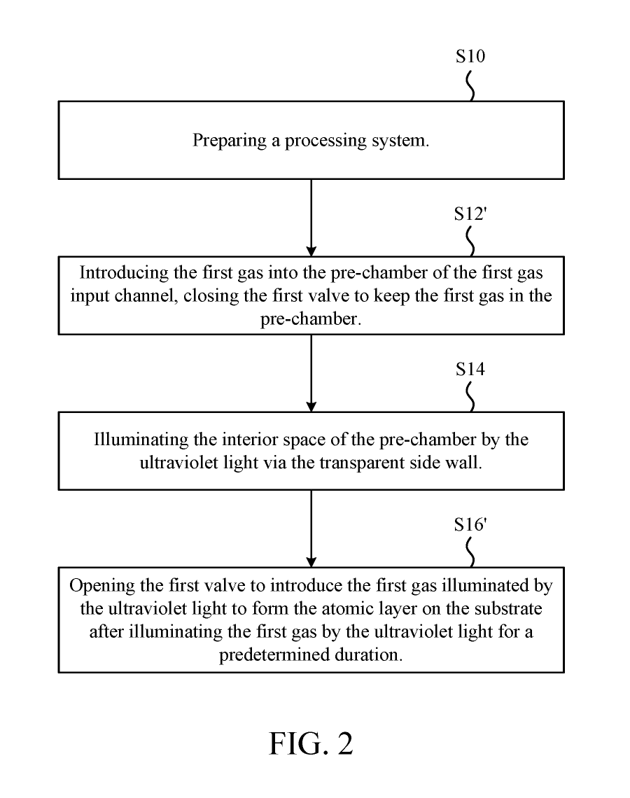

Please refer to FIG. 2 and FIG. 1B. FIG. 2 shows the flow chart of a photo-assisted atomic layer deposition method according to another embodiment of the present invention. The difference between the embodiment shown in FIG. 2 and the last embodiment is that the photo-assisted atomic layer deposition method in this embodiment further comprises step S12′ and step S16′. The other steps of the photo-assisted atomic layer deposition method are the same as the corresponding steps of the photo-assisted atomic layer deposition method in the last embodiment.

In step S12′, the first valve is closed when the first gas G1 is introduced into the pre-chamber 220 to keep the first gas G1 in the pre-chamber 220, so that the molecules of the first gas G1 can be illuminated by enough ultraviolet light in the follow-on steps. In step S16′, when the first gas G1 has been illuminated by the ultraviolet light provided by the step S14 for a predetermined duration, the first valve 222 is opened to introduce the first gas G1 into the processing chamber 20. The predetermined duration is determined by the parameters of the process and the system setup such as the kinds of the first gas G1 (precursor), the size of the processing chamber 20, and the kinds and the size of the substrate S. The first gas can be illuminated by enough ultraviolet light in the pre-chamber 220 by controlling the first valve 222.

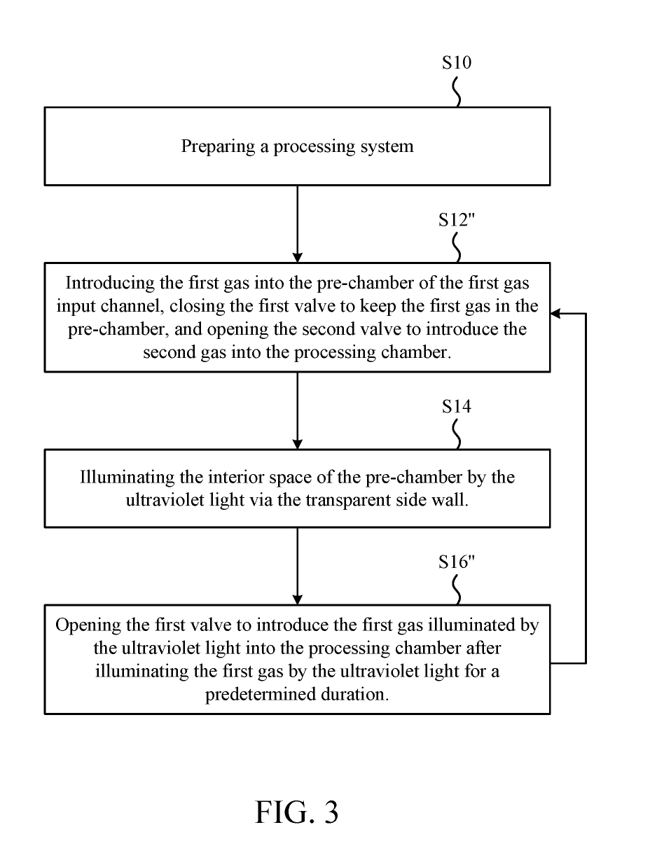

In the atomic layer deposition, there are two kinds of process gases (precursors) which are introduced into the processing chamber in turns to form the atomic layers on the substrate; for example, trimethylaluminum and water are introduced into the processing chamber to form aluminium oxides on the substrate. Please refer to FIG. 3 and FIG. 1B. FIG. 3 shows the flow chart of a photo-assisted atomic layer deposition method according to another embodiment of the present invention. The processing system 2 of FIG. 1B further comprises a second gas input channel 24 and a second valve 240 connecting the second gas input channel 24 and processing chamber 20. Besides, the second gas input channel 24 can be connected to the storage tank of the second gas G2 to receive the second gas G2 from the storage tank. As shown in FIG. 3, the difference between the embodiment and the last embodiment is that the present embodiment further comprises steps S12″ and S16″, and other steps in the present embodiment are the same as the steps of the last embodiment.

In the step S12″ in the embodiment, when the first gas G1 is introduced into the pre-chamber 220, the first valve 222 is closed to keep the first gas G1 in the pre-chamber 220, and the second valve 240 is opened to input the second gas G2 into the processing chamber 20. Therefore, in the step S14, the first gas G1 is blocked in the pre-chamber 220 to be illuminated by the ultraviolet light. In the step S16″, as the first gas G1 is illuminated by the ultraviolet light for the predetermined duration, the first valve is opened to introduced the first gas G1 into the processing chamber, and the second valve 240 is closed to block the second gas G2 from entering the processing chamber 20. One atomic layer is formed after one cycle of the steps S12″ to S16″, and it moves forward to the step S12″ of the next cycle to form another atomic layer, as shown in FIG. 3. That is to say, the first valve 222 and the second valve 240 are opened and closed alternatively to input the first gas G1 illuminated by the ultraviolet light and the second gas G2 to stack the plurality of atomic layers on the surface of the substrate S. It should be noted that the first precursor in the first cycle of the process could be the first gas G1, instead of the gas G2. Therefore, even though the second valve is opened in the step S12″, the second gas is not able to be introduced to affect the surface condition of the substrate S.

In practice, the first gas input channel 22 of the processing system 2 shown in FIG. 1B is able to comprise a third valve connecting the first gas input channel 22 and the storage tank of the first gas G1, and the third valve and the second valve are able to be opened and closed at the same time. That is to say, when the second valve 240 and the third valve are opened and the first valve 222 is closed, the second gas G2 is able to be introduced into the processing chamber to form the atomic layer on the substrate S, and the first gas G1 is introduced into the pre-chamber 220 but blocked from the processing chamber 20 to be illuminated by the ultraviolet light. When the first valve 222 is opened, the second valve 240 and the third valve are closed, so as to input the first gas G1 illuminated by enough ultraviolet light into the processing chamber 20 and to block the second gas G2. The third valve is closed when the first valve 222 is opened to make sure that the first gas G1 introduced into the processing chamber 20 has been illuminated by enough ultraviolet light.

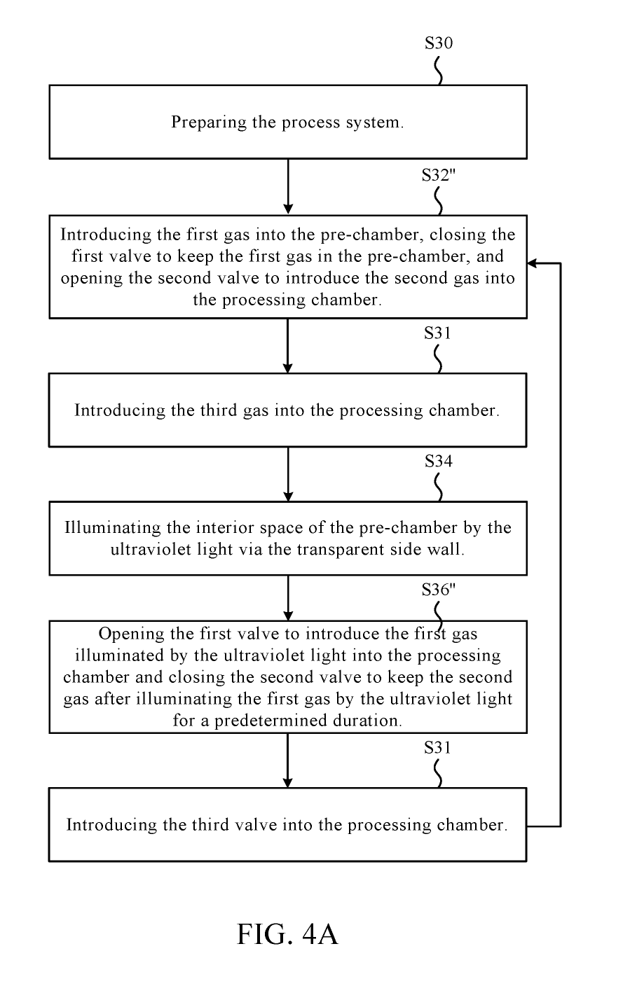

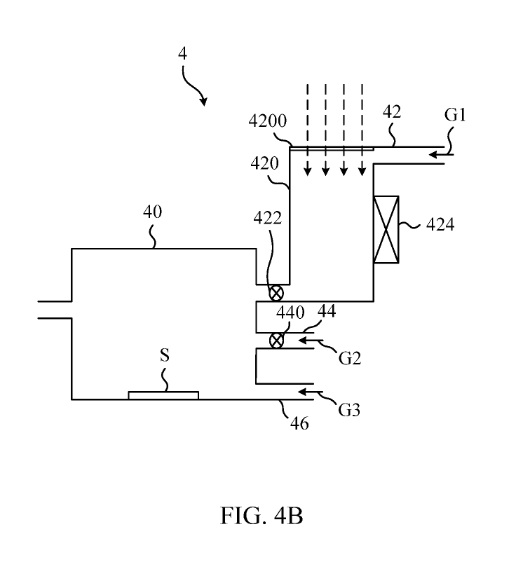

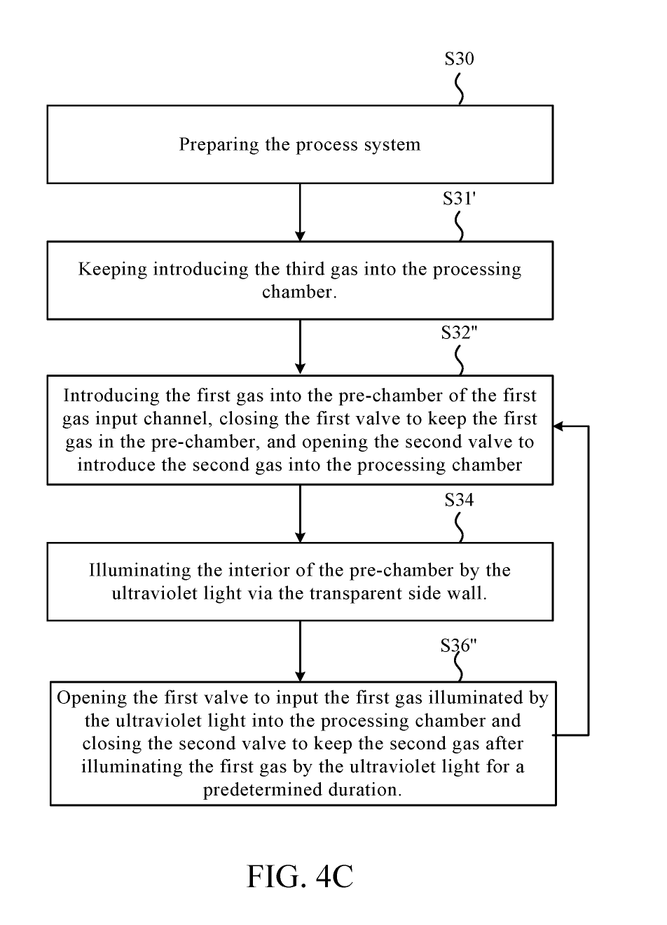

In addition to the first gas G1 and the second gas G2, the photo-assisted atomic layer deposition method of the present invention is able to utilize a third gas to assist the process. Please refer to FIG. 4A and FIG. 4B. FIG. 4A shows the flow chart of a photo-assisted atomic layer deposition method according to another embodiment of the present invention. FIG. 4B shows the diagram of the processing system applying the photo-assisted atomic layer deposition method of FIG. 4A. The difference between the processing system 4 shown in FIG. 4B and the processing system 2 shown in the embodiments mentioned above is that the processing system 4 further comprises a third gas input channel 46 connected to the processing chamber 40. The third gas input channel 46 is able to be connected to the storage tank of the third gas G3 which is not shown in the figure to input the third gas G3 into the processing chamber 40 from the storage tank.

As shown in FIG. 4A, the photo-assisted atomic layer deposition method in the present embodiment further comprises the following step of: in the step 31, introducing the third gas G3 into the processing chamber 40 via the third gas input channel 46. In the embodiments, the third gas G3 is able to be an inert gas like Ar or N₂ to maintain the stable circumstance in the processing chamber 40. Besides, the step S31 is able to be carried out once a reaction of a ALD process is completed, so as to bring the previous residual reaction gas out by the inert gas.

Please refer to FIG. 4C and FIG. 4B. FIG. 4C shows the flow chart of a photo-assisted atomic layer deposition method according to another embodiment of the present invention. As shown in FIG. 4C, the difference between the present embodiment and the last embodiment is that the step S31′ of the photo-assisted atomic layer deposition method is continually introducing the third gas G3 into the processing chamber 40. In the embodiment, the third gas G3 is a plasma gas. After the third gas is introduced into the processing chamber 40, the plasma is ignited by an electrical field. Therefore, the photo-assisted atomic layer deposition method in the embodiment is able to utilize the plasma to facilitate the atomic layer deposition and accelerate the growth rate of each atomic layer.

The processing chamber of the photo-assisted atomic layer deposition method of the present invention is able to maintain a process temperature to keep the process fluent. Besides, according to another embodiment, the photo-assisted atomic layer deposition method further comprises the following step of heating the pre-chamber 420 by the heating device 424 to make the temperature of the pre-chamber 420 in a temperature range from 25° C. to 400° C. Therefore, the first gas G1 achieves a higher reactivity to make the deposition rate faster and the required illuminating duration shorter.

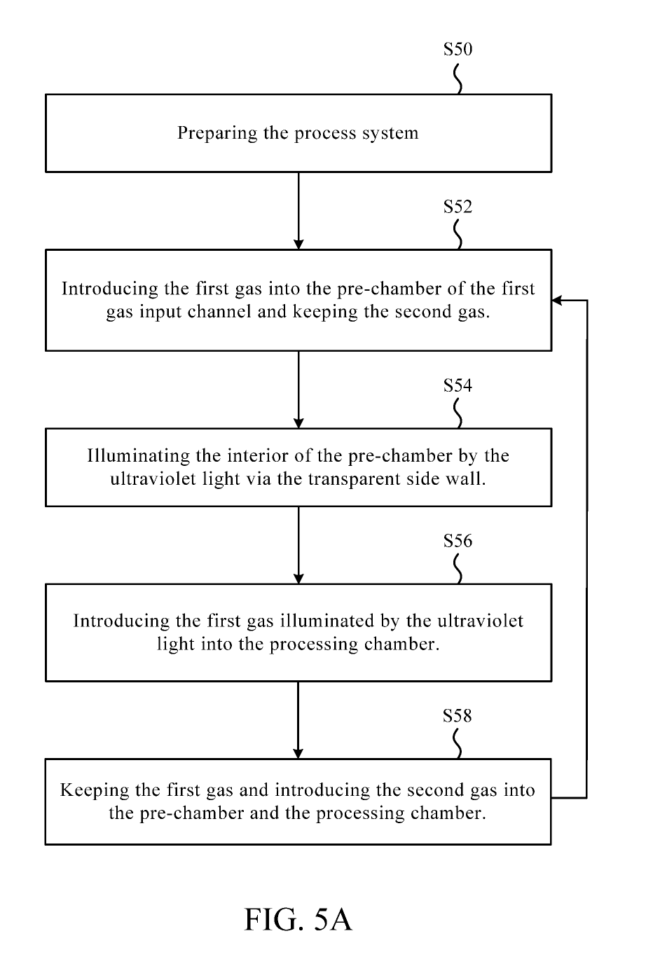

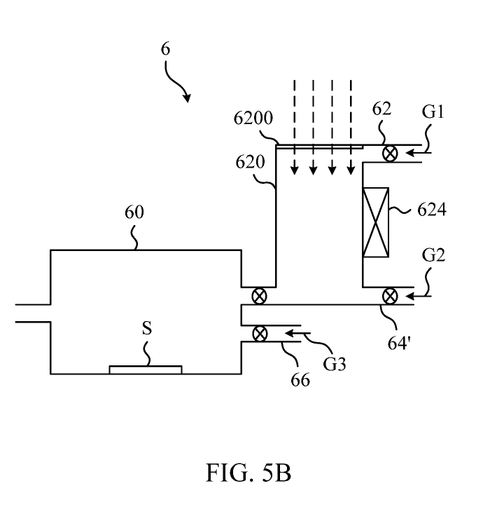

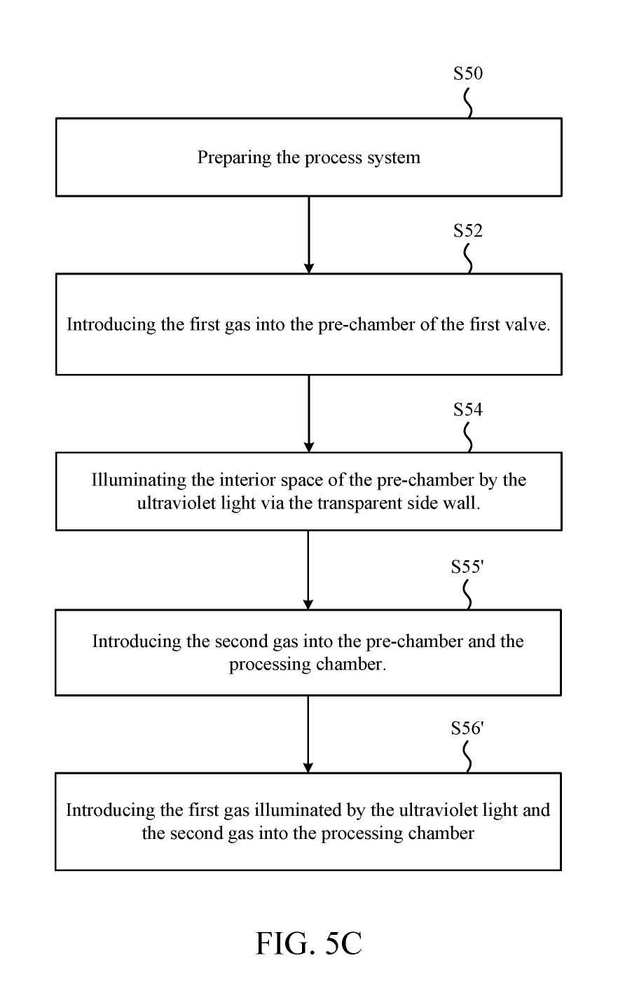

Please refer to FIG. 5A and FIG. 5B. FIG. 5A shows the flow chart of a photo-assisted atomic layer deposition method according to another embodiment of the present invention. FIG. 5B shows the diagram of the processing system applying the photo-assisted atomic layer deposition method of FIG. 5A. The difference between the processing system 6 shown in FIG. 5B and the processing chamber of the other embodiments mentioned above is that the processing system 6 further comprises the second gas input channel 64′ connected to the pre-chamber 620 of the first gas input channel 62. The other elements of the processing chamber 6 are the same as the processing chambers of the embodiments mentioned above.

As shown in FIG. 5A, the photo-assisted atomic layer deposition method in the embodiment comprises the following steps of: in the step S50, preparing the processing system 6 as shown in FIG. 5B; in the step S52, introducing the first gas G1 into the pre-chamber 620 of the first gas input channel 62 and blocking the second gas G2; in the step S54, illuminating the first gas G1 in the pre-chamber 620 by the ultraviolet light; in the step S56, introducing the first gas G1 illuminated by the ultraviolet light into the processing chamber 60 to form the atomic layer on the substrate S; and in the step S58, blocking the first gas G1 and introducing the second gas G2 into the pre-chamber 620 via the second gas input channel 64′. After finishing the step S58, restart the step S52 to repeat the cycles.

In the embodiments, the second gas G2 can work as a precursor and be introduced into the processing chamber 60 from the pre-chamber 620. When the second gas G2 is a precursor, the first gas G1 and the second gas G2 can be introduced into the pre-chamber 620 and the processing chamber 60 in turns to form the atomic layers one by one. Please refer to FIG. 5C and FIG. 5B. FIG. 5C shows the flow chart of a photo-assisted atomic layer deposition method according to another embodiment of the present invention. The difference between this embodiment and the last embodiment is that the method of the embodiment further comprises the steps S55′ and S56′. In step S55′, the second gas G2 is introduced, and the second gas G2 can be an inert gas or other assisting gas. When the second gas G2 is an inert gas or other assisting gas, in the step S56′, the second gas G2 can be introduced into the processing chamber 60 with the first gas G1 to form the atomic layers.

In the embodiments of FIG. 5A to FIG. 5C; the processing system 6 further comprises the third gas input channel 66 which can be connected to the processing chamber 60. In the step S58 of the FIG. 5A, the second gas G2 introduced via the second gas input channel 64′ is a process gas, so that the assisting gas such as the inert gas and the plasma gas can be introduced via the third gas input channel 66. Oppositely, in the step S55′ of FIG. 5C, the second gas G2 introduced via the second gas channel 64′ is an inert gas, so that the process gas can be introduced via the third gas input channel 66. It should be noted that the valves configured on each of the gas input channels in FIG. 5 are used to control the flow and the duration of different gases injecting into the processing chamber and the pre-chamber.

The photo-assisted atomic layer deposition method of the present invention utilizes the design of the pre-chamber in the gas input channel to enhance the reactivity of precursor molecules through an effective illumination of ultraviolet light. Therefore, the present invention provides a photo-assisted atomic layer deposition method utilizing the design of a pre-chamber through which the temperature of precursor molecules and the illumination of ultraviolet light can be well controlled, improving the reactivity, deposition rate and reducing the residues of the ligand functional groups of the precursor.

With the examples and explanations mentioned above, the features and spirits of the invention are well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A photo-assisted atomic layer deposition method, comprising the following steps of:
preparing a processing system, wherein the processing system comprises a processing chamber and a first gas input channel, the processing chamber is used for placing a substrate therein, the first gas input channel comprises a pre-chamber and a heating device, the pre-chamber comprising a transparent side wall is separated from the processing chamber by a first valve;
starting the heating device to raise a temperature of the pre-chamber to a predetermined temperature;
closing the first valve and introducing a first gas into the pre-chamber of the first gas input channel;
illuminating an interior space of the pre-chamber by an ultraviolet light via the transparent side wall for a predetermined duration; and
opening the first valve to introduce the first gas illuminated by the ultraviolet light into the processing chamber to form an atomic layer on the substrate.

2. The photo-assisted atomic layer deposition method of claim 1, further comprising the following step of:
heating the pre-chamber by the heating device to make the temperature of the pre-chamber in a temperature range from 25° C. to 400° C.

3. The photo-assisted atomic layer deposition method of claim 1, wherein the predetermined duration for the illumination of an ultraviolet light is in a range from 0.1s to 10s.

4. The photo-assisted atomic layer deposition method of claim 1, wherein the wavelength of the ultraviolet light is in a range from 160 nm to 360 nm.

5. The photo-assisted atomic layer deposition method of claim 1, wherein a power of the ultraviolet light is in a range from 100 Watts to 500 Watts.

6. The photo-assisted atomic layer deposition method of claim 1, wherein a temperature of the substrate heated in the processing chamber is in a range from 25° C. to 800° C.

7. The photo-assisted atomic layer deposition method of claim 1, wherein a thickness of the atomic layer in every single deposition cycle is less than 1 nm.

8. The photo-assisted atomic layer deposition method of claim 1, wherein the transparent side wall of the pre-chamber is made from one of the following materials: magnesium fluoride, quartz and glass with high penetrability of the ultraviolet light.

9. The photo-assisted atomic layer deposition method of claim 1, wherein the processing system further comprises a second gas input channel connected to the first gas input channel, the method further comprising the following step of:
introducing a second gas into the pre-chamber via the second gas input channel.

10. The photo-assisted atomic layer deposition method of claim 9, further comprising the following step of:
introducing the second gas into the processing chamber from the pre-chamber to form the atomic layer on the substrate.

11. The photo-assisted atomic layer deposition method of claim 9, wherein the second gas comprises at least one of oxygen, water, hydrogen and nitrogen.

12. The photo-assisted atomic layer deposition method of claim 1, wherein the processing system further comprises a second gas input channel connected to the processing chamber, the method further comprising the following step of:
introducing a second gas into the processing chamber via the second gas input channel to process the substrate processed by the first gas to form the atomic layer on the substrate.

13. The photo-assisted atomic layer deposition method of claim 12, wherein the processing system further comprises a second valve connecting the second gas input channel and the processing chamber, the method further comprising the following steps of:
opening the first valve and closing the second valve to input the first gas into the processing chamber via the first gas channel and to block the second gas from the second gas channel going into the processing chamber; and
closing the first valve and opening the second valve to block the first gas from the first gas channel going into the processing chamber and to input the second gas into the processing chamber via the second gas channel.

14. The photo-assisted atomic layer deposition method of claim 1, wherein the processing system further comprises a third gas input channel connected to the processing chamber, the method further comprising the following step of:
introducing a third gas into the processing chamber via the third gas input channel.

15. The photo-assisted atomic layer deposition method of claim 14, wherein the third gas comprises one of an inert gas and a plasma gas.

16. The photo-assisted atomic layer deposition method of claim 15, wherein the inert gas comprises argon and nitrogen.

17. The photo-assisted atomic layer deposition method of claim 1, further comprising the following step of:
providing plasma in the first gas input channel.

18. The photo-assisted atomic layer deposition method of claim 1, wherein the first gas is selected from the group consisting of Ti, Zr, Hf, Nb, Ta, Cr, Mo, W, Re, Fe, Co, Ni, Si, Ge, In, Sn, Ga compounds, and the combination therefore.
